(19) United States
(12) Patent Application Publication
(10) Pub. No.: US 2026/0181925 A1
(43) Pub. Date: Jun. 25, 2026

(54) COMPACT ESD STRUCTURE

(71) Applicant: Qorvo US, Inc., Greensboro, NC (US)

(72) Inventors: Peter J. Zampardi, Newbury Park, CA (US); Kathleen Muhonen, Greensboro, NC (US)

(21) Appl. No.: 18/725,462

(22) PCT Filed: Jan. 3, 2023
(86) PCT No.: PCT/US2023/010067

§ 371 Date: Jun. 28, 2024

Related U.S. Application Data
(60) Provisional application No. 63/296,896, filed on Jan. 6, 2022.

(51) Int. Cl. H10D 10/01; H10D 62/10; H10D 62/13; H10D 62/17; H10D 89/60

(52) U.S. Cl. CPC H10D 10/021; H10D 10/054; H10D 62/107; H10D 62/115; H10D 62/137; H10D 62/177; H10D 89/711; H10D 89/713

(57) ABSTRACT

A compact electrostatic discharge (ESD) structure comprises a substrate; a sub-collector region over the substrate; a collector region over a first portion of the substrate; and a base region over the collector region; an emitter region over the base region, wherein the emitter region, the base region, and the collector region form a bipolar transistor. A cathode region is provided over a second portion of the substrate. An anode contact is provided over the cathode region, wherein the cathode region and the anode contact form a Schottky diode. An emitter/anode bridge electrically couples the emitter region to the anode contact, wherein the collector region and the cathode region are electrically coupled via the sub-collector region such that the bipolar transistor and the Schottky diode are connected in an anti-parallel.

### RELATED APPLICATIONS

This application claims the benefit of provisional patent application Ser. No. 63/296,896, filed Jan. 6, 2022, the disclosure of which is incorporated herein by reference in its entirety.

### FIELD OF THE DISCLOSURE

The present disclosure relates to electrostatic discharge (ESD) circuitry.

### BACKGROUND

Electrostatic discharge (ESD) is the release of stored static electricity. ESD protection circuitry is often added to particular circuity to protect that circuitry from ESD events, wherein the circuitry being protected is referred to as protected circuitry. In almost all areas of electronics, there are continuing pressures to increase the performance of the protected circuitry while at the same time reducing the size of the protected circuitry. These pressures apply to the ESD protection circuitry as well. As such, there is a continuing need for more compact ESD protection circuitry without impacting the performance of the ESD protection circuitry.

### SUMMARY

In one embodiment, a compact electrostatic discharge (ESD) structure is provided. The ESD structure comprises a substrate; a sub-collector region over the substrate; a collector region over a first portion of the substrate; and a base region over the collector region; an emitter region over the base region, wherein the emitter region, the base region, and the collector region form a bipolar transistor. A cathode region is provided over a second portion of the substrate. An anode contact is provided over the cathode region, wherein the cathode region and the anode contact form a Schottky diode. An emitter/anode bridge electrically couples the emitter region to the anode contact, wherein the collector region and the cathode region are electrically coupled via the sub-collector region such that the bipolar transistor and the Schottky diode are connected in an anti-parallel.

In one embodiment, the compact ESD structure may further comprise an emitter contact over the emitter region, wherein the emitter/anode bridge is coupled to the emitter region.

In one embodiment, the compact ESD structure may further comprise a collector/cathode contact over a third portion of the sub-collector region, wherein the third portion is between the first portion and the second portion.

In one embodiment, the compact ESD structure may further comprise a base contact over the base region.

In one embodiment, there are no isolation regions between the bipolar transistor and the Schottky diode. At least one isolation region may be provided about a periphery of a region that includes the bipolar transistor and the Schottky diode.

In one embodiment, the collector region is thicker than the cathode region.

In one embodiment, the emitter region is doped with an N-type material, the base region is doped with a P-type material, the collector region is doped with an N-type material, the cathode region is doped with an N-type material, and the sub-collector is doped with an N-type material.

A method for forming a compact electrostatic discharge (ESD) structure may comprise:
providing a substrate;
providing a sub-collector region over the substrate;
providing a collector region over a first portion of the substrate and a cathode region over a second portion of the substrate;
providing a base region over the collector region;
providing an emitter region over the base region, wherein the emitter region, the base region, and the collector region form a bipolar transistor;
providing an anode contact over the cathode region, wherein the cathode region and the anode contact form a Schottky diode; and
providing an emitter/anode bridge electrically coupling the emitter region to the anode contact, wherein the collector region and the cathode region are electrically coupled via the sub-collector region such that the bipolar transistor and the Schottky diode are connected in an anti-parallel.

The method may further comprise providing an emitter contact over the emitter region, wherein the emitter/anode bridge is coupled to the emitter region.

The method may further comprise providing a collector/cathode contact over a third portion of the sub-collector region, wherein the third portion is between the first portion and the second portion.

The method may further comprise providing a base contact over the base region.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a circuit representation of an ESD structure.

FIG. 2 is a cross-sectional view of a compact ESD structure according to one embodiment of the disclosure.

FIG. 3 is a top view of a die layout for the compact ESD structure of FIG. 2.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

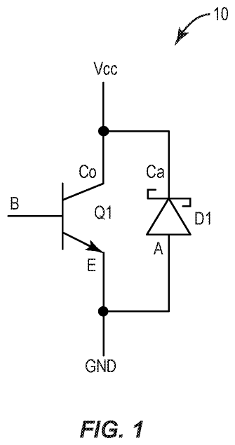

FIG. 1 illustrates an electrostatic discharge (ESD) circuit 10 that includes a bipolar transistor Q1, such as a heterojunction bipolar transistor (HBT), and a Schottky diode D1 arranged in an anti-parallel configuration. The bipolar transistor Q1 has a collector Co, base B, and emitter E in traditional fashion. The Schottky diode D1 has a cathode Ca and an anode A. The Schottky diode D1 is coupled across the bipolar transistor Q1, wherein the collector Co of the bipolar transistor Q1 is coupled to the cathode Ca of the diode D1, and the emitter E of the bipolar transistor Q1 is coupled to the anode of the diode D1. ESD circuits 10 may be used to protect various types of electronic devices from ESD events. Such electronics may include power amplifiers, low noise amplifiers, gain blocks, and the like.

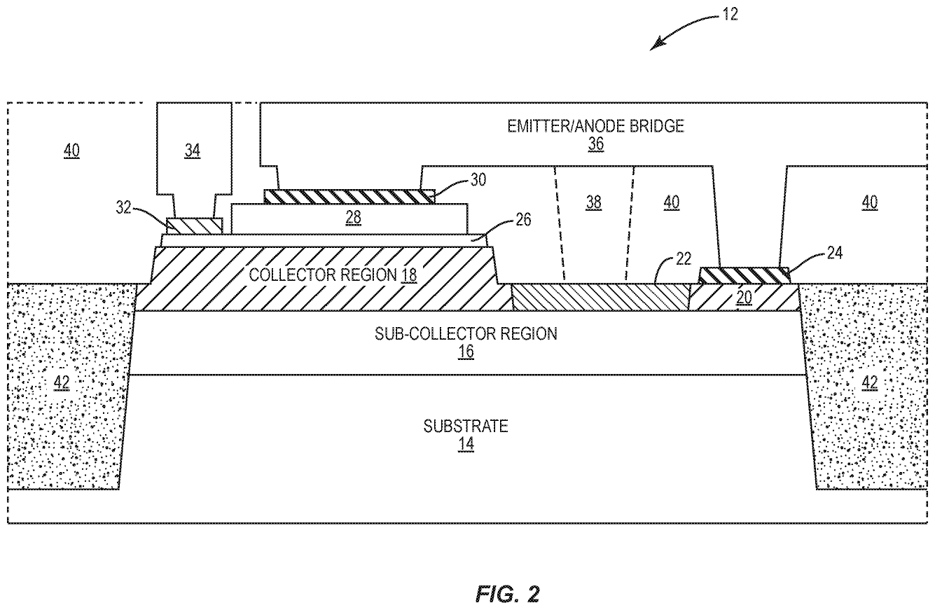

FIG. 2 is a cross-section of a novel and compact ESD structure 12 that implements the ESD circuit 10 of FIG. 1 in a very space efficient manner. For the purposes of illustration, a Gallium Arsenide (GaAs) material system is used, but other material systems may be employed. These material systems include, but are not limited to, Gallium Nitride (GaN), Silicon (Si), Silicon Germanium (SiGe), Silicon Carbide (SIC), Indium Phosphide (InP), Indium Aluminum Arsenide (InAIAs), GaAs, ternary compounds formed from these, and the like.

The foundation of the compact ESD structure 12 is a semi-insulating substrate 14 on which various epitaxial layers are formed. The epitaxial layers may include a sub-collector region 16 over the substrate 14. A collector region 18 for the bipolar transistor Q1 and a cathode region 20 for the Schottky diode D1 are formed over different portions of the sub-collector region 16. The collector region 18 and the cathode region 20 may be formed from the same or different layers and are separated from each other by a collector/cathode contact 22, which also resides on the sub-collector region 16.

In one embodiment, an anode contact 24 for the Schottky diode D1 is formed over the cathode region 20. The anode contact 24 is metal and provides a Schottky contact for the diode. The cathode region 20 is doped with an N-type material such that the junction of the metal of the anode contact 24 and the N-type material of the cathode region 20 form the Schottky diode D1.

For the bipolar transistor Q1, a base region 26 resides over the collector region 18. An emitter region 28 resides over the base region 26, wherein the emitter, base, and collector of the bipolar transistor Q1 are respectively formed by the emitter region 28, base region 26, and collector region 18. The emitter region 28 is doped with an N-type material, the base region 26 is heavily doped with a P-type material, and the collector region 18 is doped with an N-type material. An emitter contact 30 is provided over the emitter region 28, and a base contact 32 is provided over the base region and beside the emitter region 28.

In one embodiment, the sub-collector region 16 is highly doped with an N-type material to provide a highly conductive and low resistivity connection internally between the emitter region 28 of the bipolar transistor Q1 and the cathode region 20 of the Schottky diode D1. As illustrated, both the emitter region 28 and the cathode region 20 may sit directly on the sub-collector region 16 to provide a highly effective internal, electrical connection between the collector region 18 of the bipolar transistor Q1 and the cathode region 20 of the Schottky diode D1. With this internal electrical connection, an additional or alternative electrical connection using metal traces, interconnects, or structures is no longer needed. Other epitaxial regions and/or layers may be provided between these respective regions as long as the conductivity remains sufficiently high and the resistivity remans sufficiently low to provide the desired ESD functionality without departing from the concepts disclosed herein.

Connection between the emitter region 28 and the anode contact 24 is provided using an emitter/anode bridge 36, which is a metal interconnect structure that extends between the anode contact 24 ad the emitter contact 30. A metal base feed 34 is a metal structure that leads to the base contact 32. Similarly, a collector/cathode feed 38 is a metal structure that leads to the collector cathode contact 22.

A dielectric 40 may be provided above and/or around the various regions, contacts, and structures that reside at, on, or near the surface of the ESD structure 12. Further, isolation regions 42 may be provided about the sub-collector region 16 and into the substrate 14 for the ESD 12. The isolation regions 42 may be formed by damaging desired portions of the substrate 14 and the epitaxial structure thereon to create highly resistive regions. The dielectric 40 may also reside over these isolation regions 42, as illustrated in FIG. 2.

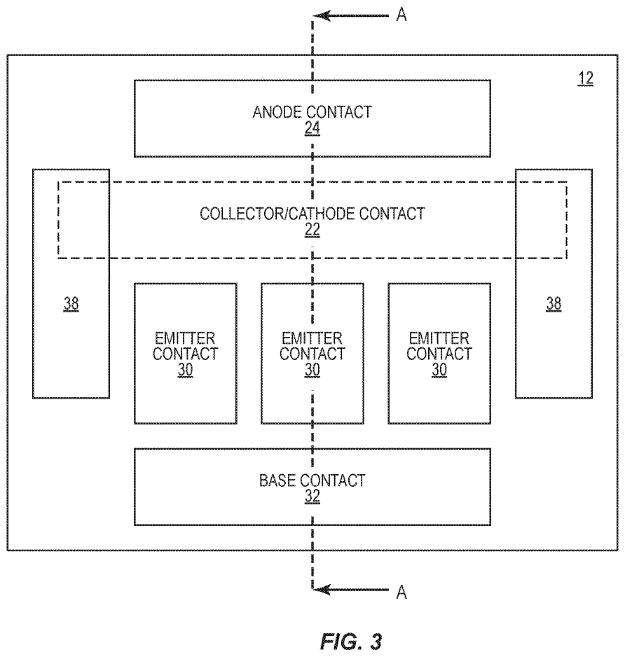

FIG. 3 illustrates a top view of the ESD structure 12, wherein the cross-section line A-A corresponds to the cross-section of FIG. 2. The emitter/anode bridge 36 is not depicted. A key benefit of using the sub-collector region 16 to provide the electrical connection between the collector region 18 of the bipolar transistor Q1 and the cathode region 20 of the Schottky diode D1 is how compact the layout becomes. Such compactness is made possible by eliminating the need for separate collector and cathode contacts and an interconnect to connect them, and essentially using a single contact, the collector/cathode contact 22, to facilitate a contact to both the collector region 18 of the bipolar transistor Q1 and the cathode region 20 of the Schottky diode D1. Further, there is no isolation region 42 provided between the two components. The space savings are substantial.

Further, the performance of the compact ESD structure 12 is essentially equivalent to the that of its predecessor that did not employ the concepts disclosed herein.

The following provides exemplary materials, thicknesses, doping ranges, and the like for certain of the layers, regions, and parts of the compact ESD structure 12. These materials, thicknesses, doping ranges, and the like are merely examples and should not be construed as limiting, unless specifically stated.

The substrate 14 may have a thickness in the range of 5 um to 800 um or 100 um-200 um, be formed from GaAs, Si, InP, or the like, and be unintentionally doped, semi-insulating, or the opposite charge doping of the sub-collector, or the like at a concentration of nid-1e19 cm-3 (p or n) or nid. The sub-collector region 18 may have a thickness in the range of 0.5 um to 1.2 um or 0.6 um to 0.9 um, be formed from GaAs, Ge, InP, InGaAs, or the like, and be doped with an N-type dopant such as Si, Te, Se, or the like at a concentration of 1e18 cm-3-1e19 cm-3 or 3e18-5e18 cm-3.

The collector region 18 and the cathode region 20 may be formed from a common layer. In certain embodiments, the collector region 18 is thicker than the cathode region 20 and may consist of multiple doping regions. The collector region 18 may have a thickness in the range of 0.3 um to 1.1 um or 0.85-1.1 um, be formed from GaAs, InGaP, InP, or the like, and be doped with an N-type dopant such as Si or the like at a concentration of 2.5e15 cm-3 to 5e18 cm-3 (broad range) or 1e16 cm-3 to 5e16 cm-3. The cathode region 20 may have a thickness in the range of 0.15 um to 1 um (broad range) or 0.45-0.55 um, be formed from identical materials to the collector region.

The collector/cathode contact 22, the anode contact 24, and the base contact 32 may be formed a metal or other highly conductive material, such as, AuNiGe, Pt/Ti/Pt/Au, PdGe, or the like. The emitter region 28 may have a thickness in the range of 200 A to 500 A or 300 A to 400 A, be formed from InGaP, AIGaAs, InP, or the like, and be doped with an N-type dopant such as Si, ______, or the like at a concentration of 5e16 cm-3 to 5e17 cm-3 or 2.5e17 to 3.5e17 cm-3. The base region 26 may have a thickness in the range of 350 A to 1000 A or 550 A to 750 A, be formed from GaAs, InGaAs, GaAsSb, or the like, and be doped with an N-type dopant such as C, Be, a combination, or the like at a concentration of 1e19 cm-3 to 1e20 cm-3 or 2e19 cm-3 to 6e19 cm-3.

The base feed 34, the collector/cathode feed 38, and the emitter/anode bridge may be formed from Au, Cu, or the like. The dielectric 40 may be formed from SIN, BCB, Polyimide, or the like. The isolation regions 42 may be amorphized through crystalline damage.

The polarity may be interchanged (PNP for NPN) but the turn-on for the p-type Schottky would require other changes or processing to make it have a reasonable turn-on voltage compared to the n-type version. (Waldrop APL, 44, 1002, 1984 or Okumura, Journal of Applied Physics, 61, 2955, 1987, incorporated herein by reference in its entirety.)

Those skilled in the art will recognize improvements and modifications to the preferred embodiments of the present disclosure. All such improvements and modifications are considered within the scope of the concepts disclosed herein and the claims that follow.

What is claimed is:

1. A compact electrostatic discharge (ESD) structure comprising:
a substrate;
a sub-collector region over the substrate;
a collector region over a first portion of the sub-collector region;
a base region over the collector region;
an emitter region over the base region, wherein the emitter region, the base region, and the collector region form a bipolar transistor;
a cathode region over a second portion of the sub-collector region;
an anode contact over the cathode region, wherein the cathode region and the anode contact form a Schottky diode; and
an emitter/anode bridge electrically coupling the emitter region to the anode contact, wherein the collector region and the cathode region are electrically coupled via the sub-collector region such that the bipolar transistor and the Schottky diode are connected in an anti-parallel.

2. The compact ESD structure of claim 1 further comprising an emitter contact over the emitter region, wherein the emitter/anode bridge is coupled to the emitter contact.

3. The compact ESD structure of claim 2 further comprising a collector/cathode contact over a third portion of the sub-collector region, wherein the third portion is between the first portion and the second portion.

4. The compact ESD structure of claim 3 further comprising a base contact over the base region.

5. The compact ESD structure of claim 1 wherein there are no isolation regions between the bipolar transistor and the Schottky diode.

6. The compact ESD structure of claim 5 wherein at least one isolation region is provided about a periphery of a region that includes the bipolar transistor and the Schottky diode.

7. The compact ESD structure of claim 1 wherein the collector region is thicker than the cathode region.

8. The compact ESD structure of claim 1 wherein the emitter region is doped with an N-type material, the base region is doped with a P-type material, the collector region is doped with an N-type material, the cathode region is doped with an N-type material, and the sub-collector region is doped with an N-type material.

9. A compact electrostatic discharge (ESD) structure comprising:
a substrate;
a sub-collector region over the substrate;
a collector region over a first portion of the sub-collector region;
a base region over the collector region;
an emitter region over the base region, wherein the emitter region, the base region, and the collector region form a bipolar transistor;
a cathode region over a second portion of the sub-collector region;
an anode contact over the cathode region, wherein the cathode region and the anode contact form a Schottky diode;
an emitter/anode bridge electrically coupling the emitter region to the anode contact, wherein the collector region and the cathode region are electrically coupled via the sub-collector region such that the bipolar transistor and the Schottky diode are connected in an anti-parallel;
an emitter contact over the emitter region, wherein the emitter/anode bridge is coupled to the emitter contact;
a collector/cathode contact over a third portion of the sub-collector region, wherein the third portion is between the first portion and the second portion; and
a base contact over the base region.

10. The compact ESD structure of claim 9 wherein there are no isolation regions between the bipolar transistor and the Schottky diode.

11. The compact ESD structure of claim 10 wherein at least one isolation region is provided about a periphery of a region that includes the bipolar transistor and the Schottky diode.

12. The compact ESD structure of claim 11 wherein the collector region is thicker than the cathode region.

13. The compact ESD structure of claim 9 wherein the emitter region is doped with an N-type material, the base region is doped with a P-type material, the collector region is doped with an N-type material, the cathode region is doped with an N-type material, and the sub-collector region is doped with an N-type material.

14. A method for forming a compact electrostatic discharge (ESD) structure comprising:
providing a substrate;
providing a sub-collector region over the substrate;
providing a collector region over a first portion of the sub-collector region and a cathode region over a second portion of the sub-collector region;
providing a base region over the collector region;
providing an emitter region over the base region, wherein the emitter region, the base region, and the collector region form a bipolar transistor;
providing an anode contact over the cathode region, wherein the cathode region and the anode contact form a Schottky diode; and
providing an emitter/anode bridge electrically coupling the emitter region to the anode contact, wherein the collector region and the cathode region are electrically coupled via the sub-collector region such that the bipolar transistor and the Schottky diode are connected in an anti-parallel.

15. The method of claim 14 further comprising providing an emitter contact over the emitter region, wherein the emitter/anode bridge is coupled to the emitter contact.

16. The method of claim 15 further comprising providing a collector/cathode contact over a third portion of the sub-collector region, wherein the third portion is between the first portion and the second portion.

17. The method of claim 16 further comprising providing a base contact over the base region.

18. The method of claim 14 wherein there are no isolation regions between the bipolar transistor and the Schottky diode.

19. The method of claim 18 wherein at least one isolation region is provided about a periphery of a region that includes the bipolar transistor and the Schottky diode.

20. The method of claim 14 wherein the collector region is thicker than the cathode region.

21. The method of claim 14 wherein the emitter region is doped with an N-type material, the base region is doped with a P-type material, the collector region is doped with an N-type material, the cathode region is doped with an N-type material, and the sub-collector region is doped with an N-type material.
